(19) United States
(12) Patent Application Publication
(10) Pub. No.: US 2021/0013653 A1
(43) Pub. Date: Jan. 14, 2021

(54) CONNECTORS WITH METAMATERIALS

(71) Applicant: Samtec, Inc., New Albany, IN (US)

(72) Inventors: Yasuo SASAKI, Yokohama-shi (JP); Kevin R. MEREDITH, New Albany, IN (US)

(21) Appl. No.: 16/977,201

(22) PCT Filed: May 8, 2019
(86) PCT No.: PCT/US2019/070005

§ 371 Date: Sep. 1, 2020

Related U.S. Application Data
(60) Provisional application No. 62/668,663, filed on May 8, 2018.
(60) Provisional application No. 62/669,832, filed on May 10, 2018.

(51) Int. Cl. H01R 13/03; H05K 7/20

(52) U.S. Cl. CPC H01R 13/03; H05K 7/20409

(57) ABSTRACT

A connector includes a thermal metamaterial. The thermal metamaterial provides heat flow paths from inside of the connector to outside of the connector. In addition, an electrical connector includes an electrically insulating housing, an electrically conductive contact included in the electrically insulating housing, and a metamaterial thermally connected to one of the electrically insulating housing or the electrically conductive contact. The metamaterial thermally cools the electrical connector.

### RELATED APPLICATIONS

This application claims the benefit of U.S. Provisional Patent Application Nos. 62/668,663, filed May 8, 2018, and 62/669,832, filed May 10, 2018; which are all hereby incorporated by reference for all purposes as if fully set forth herein.

### BACKGROUND OF THE INVENTION

### 1. Field of the Invention

The present invention relates to thermal management. More specifically, the present invention relates to thermal management of connectors, including, for example, electrical connectors and modular optical connectors such as optical couplers and optical transceivers, using metamaterials.

### 2. Description of the Related Art

A connector's temperature must be controlled to ensure that the connector functions correctly. This is true if the connector is, for example, an electrical connector or an optical module such as an optical coupler or an optical transceiver, and can be achieved using proper thermal management. For example, in some applications with no forced air, a power connector's temperature should be controlled to less than about 30° C. above ambient temperature.

A terminal and a socket of a power connector can be used to transmit power. The terminal is located on a first substrate, and a socket is located on a second substrate. The terminal and the socket of the power connector can be mated together to transmit power between the first and second substrates. The socket includes socket contacts within an insulating housing, and the terminal includes terminal contacts with an insulating housing. When the socket and terminals are mated, corresponding socket contacts and terminal contacts are engaged with each to allow power to be transmitted between the first and second substrates.

Resistive heat is generated when electrical power is transmitted through the terminal and a socket of a connector system. This heat can lead to increasing temperatures. If the temperature of the connectors increases beyond a limit, then the connector system can malfunction or become degraded.

### SUMMARY OF THE INVENTION

To overcome the problems described above, preferred embodiments of the present invention use metamaterials to provide better thermal management in connectors, including, for example, electrical connectors or an optical module such as an optical coupler and an optical transceiver.

According to a preferred embodiment of the present invention, an electrical connector can include an electrically insulated housing, an electrically conductive contact included in the electrically insulating housing, and metamaterial thermally connected to one of the electrically insulating housing or the electrically conductive contact. The metamaterial thermally cools the electrical connector or the contact.

According to a preferred embodiment of the present invention, an electrical connector can include an electrically insulated housing, an electrically conductive contact carried by the electrically insulating housing, an electrically conductive shield, and metamaterial thermally connected to one of the electrically insulating housing or the electrically conductive contact or the electrically conductive shield. The metamaterial thermally cools the electrical connector or the contact.

The metamaterial preferably reduces unwanted heat by approximately 5° C.-10° C. The metamaterial preferably reduces unwanted heat by approximately 5° C.-10° C. when the electrical connector is exposed to an air velocity of 200-800 feet/minute. The metamaterial preferably reduces unwanted heat by approximately 5° C.-15° C. at 3.5 Watts, approximately 5° C.-15° C. at 7 Watts, and approximately 7° C.-15° C. at 12 Watts.

Preferably, the electrical connector is cooler with respect to an identical electrical connector devoid of the metamaterial when operated at the same current and/or power, and ambient temperature. A thermal interface material is preferably directly adjacent to at least one surface of the metamaterial. The metamaterial preferably includes an array of surface holes.

According to a preferred embodiment of the present invention, a connector can include a thermal metamaterial. The thermal metamaterial provides heat flow paths from inside the connector to outside of the connector or converts heat into radiation.

Preferably, the connector is an electrical connector, a power connector, or an optical module. The thermal metamaterial preferably includes an anisotropic composite in which high thermal conductivity fibers or asymmetric particles are included in a low thermal conductivity matrix to provide the heat flow paths. The thermal metamaterial preferably converts heat into resin-transparent radiation, i.e., radiation that is not absorbed by resin and does not heat the resin. A thermal interface material is preferably directly adjacent to at least one surface of the thermal metamaterial. The thermal metamaterial preferably includes an array of surface holes.

According to a preferred embodiment of the present invention, a cage assembly can include a cage that receives a transceiver, a heatsink connected to the cage, and metamaterial thermally connected to one of the cage or the heatsink. The metamaterial thermally cools the transceiver when the transceiver is plugged into the cage.

A thermal interface material is preferably directly adjacent to at least one surface of the metamaterial. The metamaterial preferably includes an array of surface holes.

According to a preferred embodiment of the present invention, a transceiver assembly can include the cage assembly and a transceiver plugged into the cage.

Preferably, the transceiver includes a vertical-cavity surface-emitting laser (VCSEL), and the metamaterial maintains a temperature of the VCSEL between approximately −40° C. and 125° C. The metamaterial preferably includes an array of surface holes.

According to a preferred embodiment of the present invention, a connector includes a housing, an electrical contact in the housing, and a metamaterial thermally connected to the electrical contact.

The connector preferably includes a thermal interface material located between the electrical contact and the metamaterial, a thermal interface material located between the housing and the metamaterial, or both a first thermal interface material located between the electrical contact and the metamaterial and a second thermal interface material located between the housing and the metamaterial. The metamaterial preferably includes an array of surface holes.

The above and other features, elements, characteristics, steps, and advantages of the present invention will become more apparent from the following detailed description of preferred embodiments of the present invention with reference to the attached drawings.

### BRIEF DESCRIPTION OF THE DRAWINGS

FIGS. 1-3 show metamaterials applied to a terminal contact.

FIGS. 4-6 show metamaterials applied to a socket contact.

FIGS. 7-9 show a terminal contact mated with socket contacts.

FIG. 10 shows a terminal in a housing.

FIG. 11 shows a socket in a housing.

FIGS. 12 and 13 show optical transceivers connected to a printed circuit board.

FIG. 14 shows an optical transceiver with a portion of the housing removed.

FIG. 15 shows a housing of an optical transceiver.

FIG. 16 shows the test results of an optical transceiver with metamaterials and without metamaterials in a heated wind tunnel.

FIGS. 17 and 18 show possible arrangements of the metamaterials with respect to a heat-generating element.

FIG. 19 shows a cross-section of a metamaterial.

FIG. 20 shows a top view of the metamaterial in FIG. 19.

### DETAILED DESCRIPTION

A metamaterial includes any material engineered to produce properties that do not occur naturally. Metamaterials are discussed in U.S. Patent Application Publication No. 2017/0237300; Dede et al., “Thermal Metamaterials for Heat Flow Control in Electronics,” Journal of Electronic Packaging, vol. 140, March 2018, pp. 010904-1 to 010904-10; and Biehs et al., “Nanoscale radiative heat transfer and its applications,” Infrared Radiation, InTech, Feb. 10, 2012, 27 pages. The entire contents of these three references are hereby incorporated by reference in their entirety for all purposes, as if fully set forth herein. Metamaterials can be made from assemblies of multiple elements fashioned from composite materials such as metals or plastics and can derive their properties not from the properties of the base materials, but from their structures. Metamaterials can include composite media with nanoscale features, patterns, or elements.

Some thermal metamaterials include structures that can manipulate heat flux. For example, thermal metamaterials can include an anisotropic composite that provides heat flow control by including thermally conductive paths in a heterogeneous material by orienting high thermal conductivity fibers or asymmetric particles in a preferred direction within a low thermal conductivity matrix. In such thermal metamaterials, heat tends to flow parallel to the axis of the fiber or particle, while heat flow normal to the axis of the fiber or particle is substantially reduced. For example, Al-based thermal metamaterials could be used as the metamaterial.

Some thermal metamaterials use a three-dimensional structure to convert thermal energy into radiation. Such thermal metamaterials do not rely on convection and conduction to provide thermal management. For example, nanoscale tungsten and hafnium oxide layers in a metamaterial can suppress the emission of one portion of the electromagnetic spectrum while enhancing emission in another portion of the electromagnetic spectrum. But, other materials and structures can also be used. For example, it is also possible to use a metamaterial with an array of surface holes. The dimensions and arrangement of the surface holes can be used to tune which electromagnetic emissions are suppressed and which electromagnetic emissions are enhanced. The surface holes can act as resonators such that changing the dimensions and arrangement of the surface holes changes the resonances of the holes. The converted radiation can be infrared radiation in a controlled spectrum and can be transparent to most resins. For example, the metamaterial can transmit infrared radiation that is transmitted through and that is not absorbed by the structure to which it is attached. Therefore, a housing or other resin-containing or glass-containing component of a connector are not heated by the radiation or are not substantially heated by the radiation in comparison to an identical connector without metamaterials that uses conduction and/or convection for thermal management.

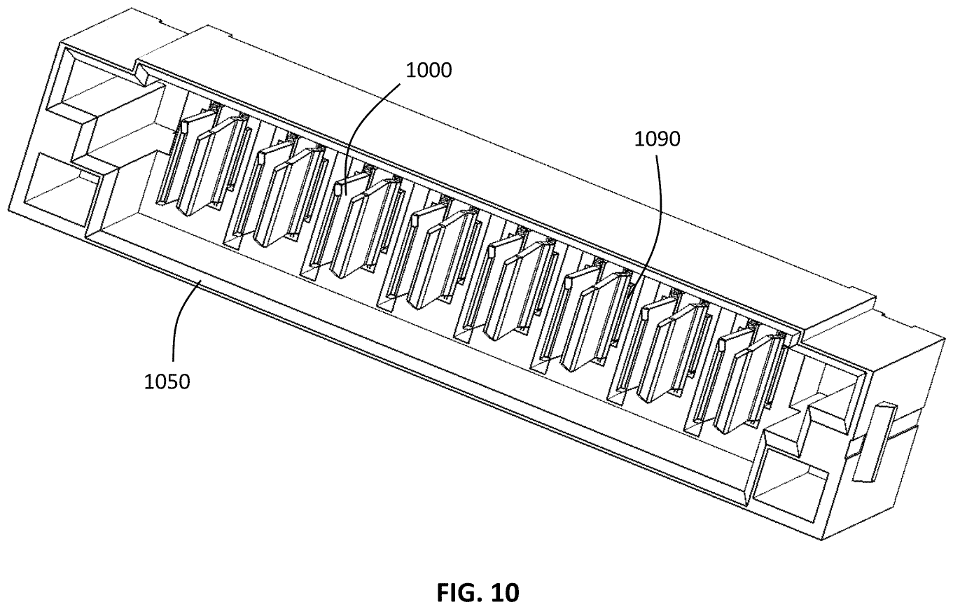

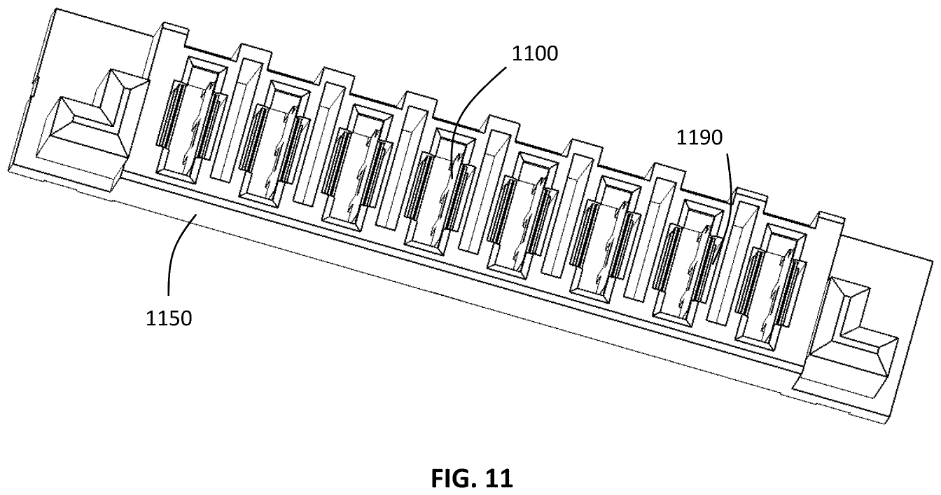

Thermal metamaterials can be used to direct heat flux of a connector to improve the thermal properties of the connector. Adding thermal metamaterial to an existing connector can help cool the connector so that more current and/or power can be transmitted through the connector before a damaging heat level is reached. Discussed below is an example of a power connector that includes a terminal and a socket as shown in FIGS. 10 and 11, but similar techniques can also be applied to other connectors, including, for example, electrical connectors other than power connectors and optical modules such as optical couplers or optical transceivers. The metamaterials can be in thermal contact with power contacts, terminal contacts, die packages, electrical-to-optical components, optical-to-electrical components, any component that requires a heatsink, etc.

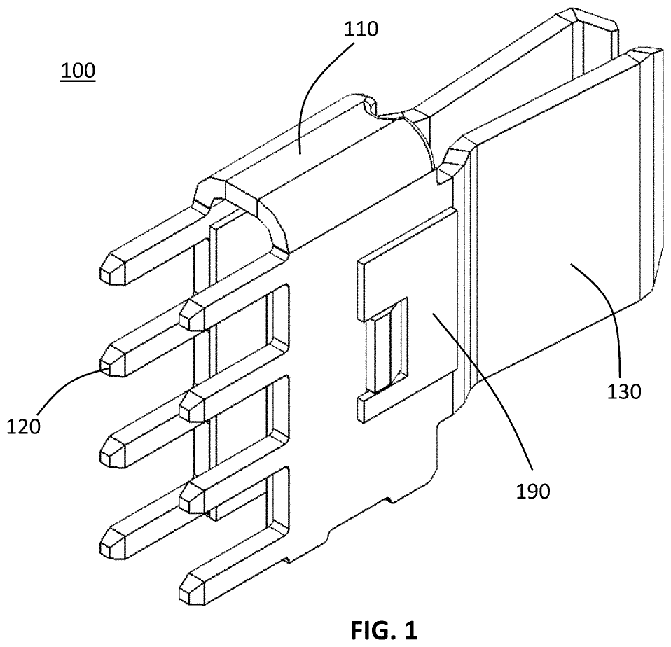

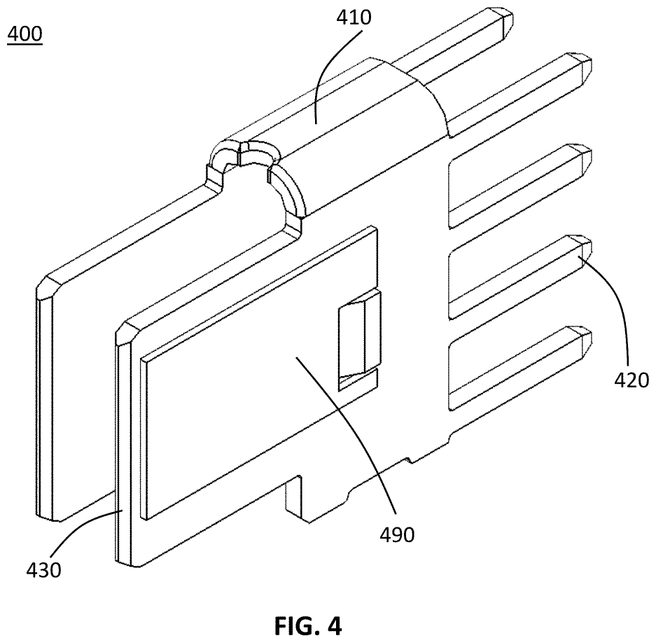

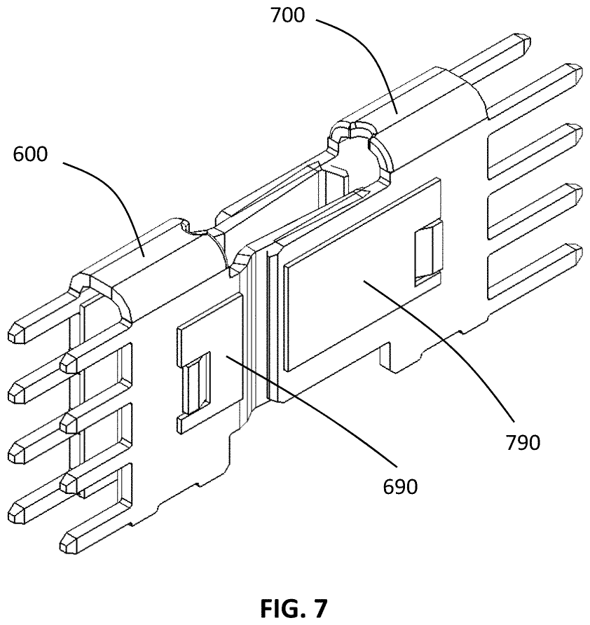

FIGS. 1-3 show a terminal contact 100, FIGS. 4-6 show a socket contact 400, and FIGS. 7-9 show terminal contact 600 and socket contact 700 mated together.

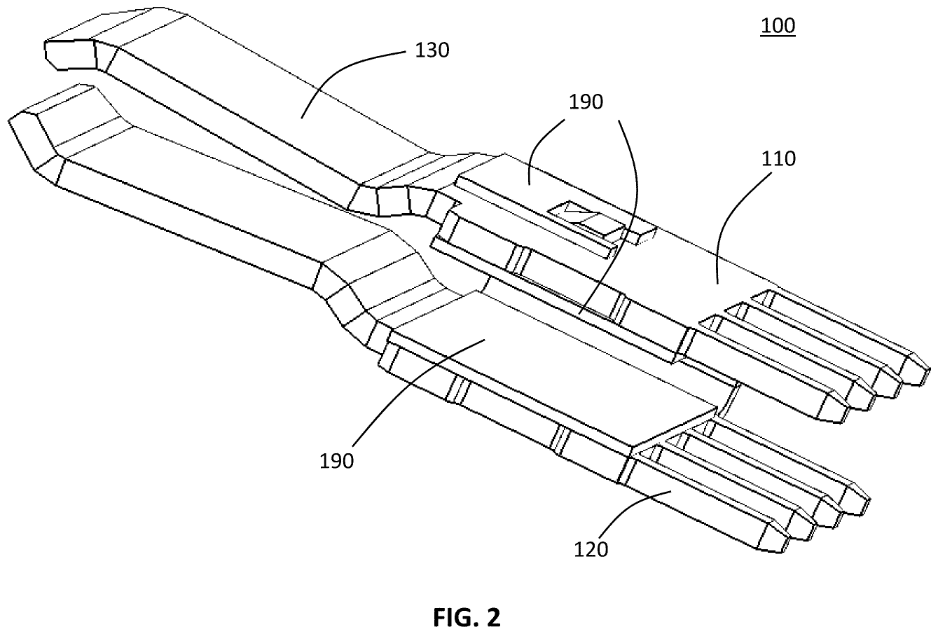

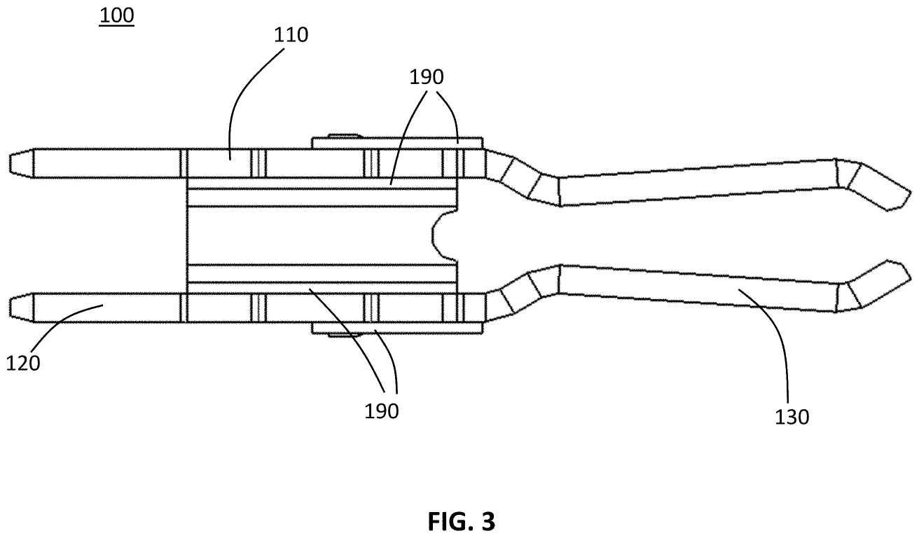

FIG. 1 is a perspective view of an exemplary connector terminal contact 100. FIG. 2 is a perspective section view of the terminal contact 100, and FIG. 3 is a side view of the terminal contact 100. As shown in FIGS. 1-3, a terminal contact 100 can include a body 110 that has a leg 120 and an arm 130 extending from the body 110, and a metamaterial 190 attached to the body 110. As shown, the terminal contact 100 of FIGS. 1-3 includes a plurality of legs 120 and arms 130.

The legs 120 can be engaged with through holes in a substrate (not shown), which is typically a printed circuit board (PCB) but could be any suitable substrate. FIGS. 1 and 2 show a terminal connector 100 with eight legs 120, but any number of legs could be used. The legs 120 can be secured to the substrate so that the terminal contact 100 cannot be disconnected from the substrate without damaging the substrate and/or the terminal contact 100. Typically, the legs 120 are soldered to the substrate, but any fusible material or any other suitable technique can be used.

FIGS. 1-3 show two opposing arms 130 that extend from the body 100. The arms 130 of the terminal contact 100 can be cantilevered to provide a spring force when the terminal contact 100 engages with corresponding arms of a socket contact, as shown in FIGS. 7-9. Any number of arms 130 can be used. For example, each of the arms 130 shown in FIGS. 1-3 could be divided to define two arms to create four total arms 130. In FIGS. 1-3, the arms 130 and legs 120 extend from opposite ends of body 110, but other arrangements are also possible. For example, the arms 130 and legs 120 can extend from the body 110 at a right angle or approximately a right angle within manufacturing tolerance. As shown in FIGS. 1-3, the terminal contact 100 can be defined by folding to create a space between the two opposing arms 130.

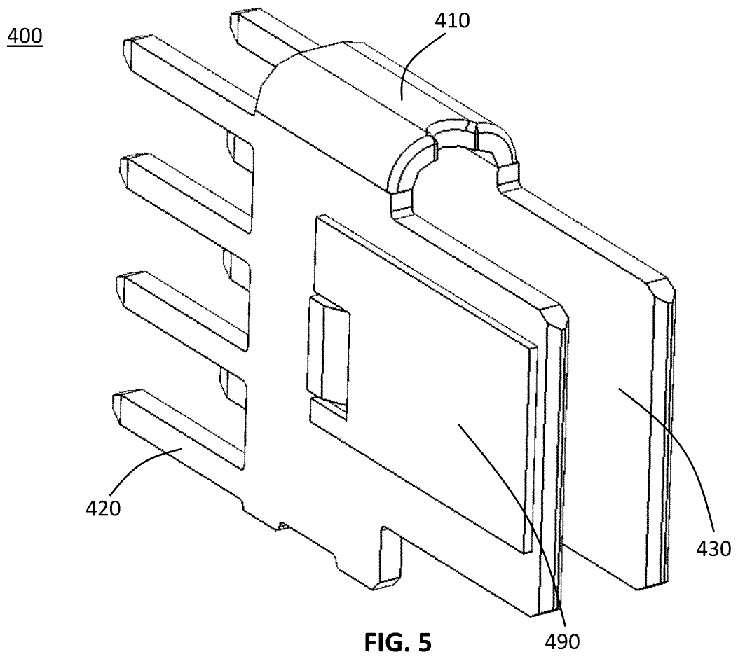

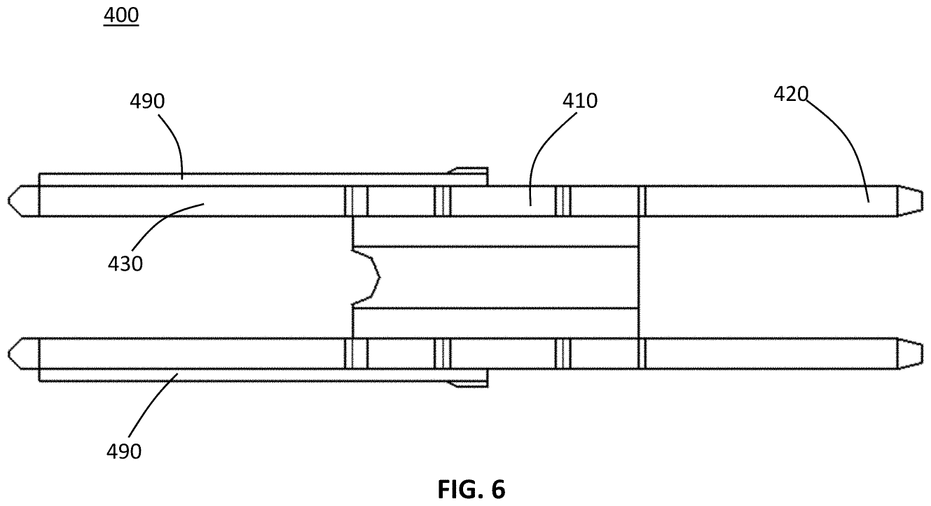

FIG. 4 is a perspective view of an exemplary connector socket contact 400. FIG. 5 is a different perspective view of the socket contact 400, and FIG. 6 is a side view of the socket contact 400. As shown in FIGS. 4-6, a socket contact 400 can include a body 410 that has a leg 420 and an arm 430 extending from the body 410, and a metamaterial 490 attached to the body 410. As shown, the socket contact 400 of FIGS. 4-6 includes a plurality of legs 420 and arms 430.

The legs 420 can be engaged with through holes in a substrate (not shown), which is typically a printed circuit board (PCB) but could be any suitable substrate. FIGS. 4 and 5 show eight legs 420, but any number of legs 420 could be used. The legs 420 can be secured to the substrate so that the socket contact 400 cannot be disconnected from the substrate without damaging the substrate and/or the socket contact 400. Typically, the legs 420 are soldered to the substrate, but any fusible material or any other suitable technique can be used.

FIGS. 4-6 show two opposing arms 430 that extend from the body 410. The arms 430 of the socket contact 400 are not cantilevered but do provide a surface with which the arms of a terminal contact can engage with when the socket contact 400 engages with corresponding arms of a terminal contact, as shown in FIGS. 7-9. Any number of arms 430 can be used. For example, each of the arms 430 shown in FIGS. 4-6 could be divided to define two arms to make four total arms 430. In FIGS. 4-6, the arms 430 and legs 420 extend from opposite ends of body 410, but other arrangements are also possible. For example, the arms 430 and legs 420 can extend from the body 410 at a right angle or approximately a right angle within manufacturing tolerance. As shown in FIGS. 4-6, the socket contact 400 can be defined by folding to create a space between the two opposing arms 430.

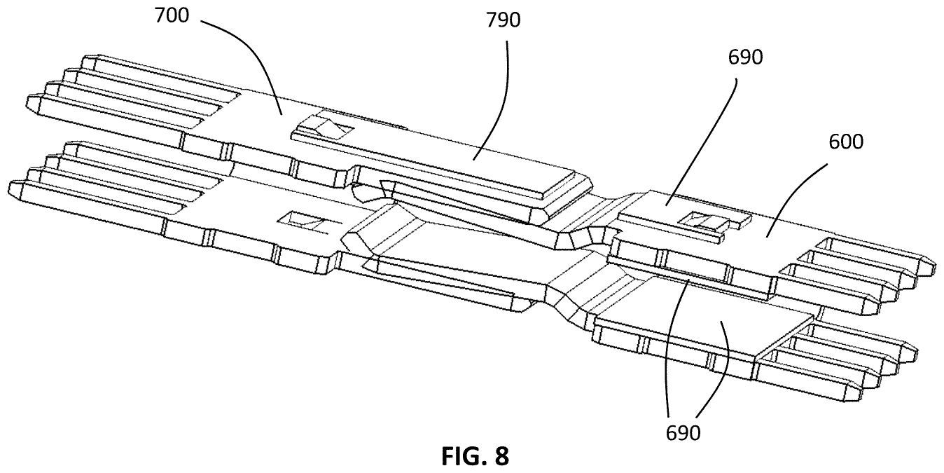

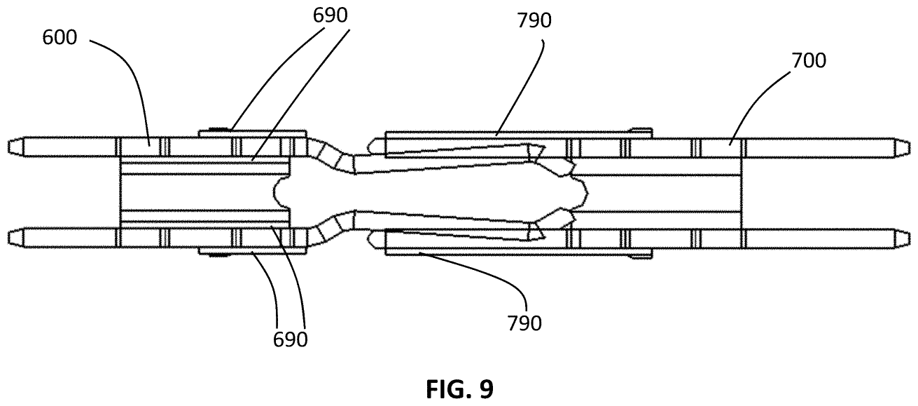

FIGS. 7-9 show a terminal contact 600 and a socket contact 700, similar to those described with respect to FIGS. 1-6, mated together. FIG. 7 is a perspective view of an exemplary connector terminal contact 600 mated to an exemplary socket contact 700. FIG. 8 is a different perspective view of the mated contacts 600, 700, and FIG. 9 is a side view of the mated contacts 600, 700. As shown in FIGS. 7-9, the terminal contact 600 and the socket contact 700 can both include a body that has a leg and an arm extending from the body, and metamaterials 690 and 790 respectively attached to the bodies. As shown, the terminal contact 600 and the socket contact 700 of FIGS. 7-9 includes a plurality of legs and arms.

FIG. 10 shows a terminal 1000 with terminal contacts and a metamaterial 1090 included in an insulating housing 1050, and FIG. 11 shows a socket 1100 with socket contacts with a metamaterial 1190 included in an insulating housing 1150. FIGS. 10 and 11 show eight contacts in each of the terminal and socket, but any number of contacts can be used. As shown in FIGS. 10 and 11, the number of terminal contacts typically match the number of socket contacts. Any suitable insulating material can be used as the insulating housings 1050, 1150. As shown in FIGS. 10 and 11, the power connector can be used to transmit only power, but it is also possible to use an electrical connector that includes power contacts in addition to signal contacts to transmit power and signals. If the electrical connector includes signal contacts, then the electrical connector can also include a conductive shield that shields the signal contacts.

Metamaterials can be added to the contacts of the power connector to improve the thermal properties of the power connector. The metamaterials can be applied to any surface of the contacts. As shown in FIGS. 1-3, metamaterials 190 can be applied to the outside and to the inside of the terminal contact 100. As shown in FIGS. 4-6, a metamaterial 490 can be applied only to the outside of the socket contact 400. If the metamaterial can be easily damaged, then, as shown in FIGS. 7-9, the metamaterials 690, 790 can be applied to the contacts outside the region where the arms 630 of the terminal contact 600 engages with the arms 730 of the socket contact 700. Instead of applying the metamaterial to the contacts, it is possible to apply the metamaterial to an insulating housing. If the power connector includes signal contacts, then the metamaterial can also be applied to the signal contacts. If the power connector includes a conductive shield, then a metamaterial can also be applied to the conductive shield.

Any arrangement of metamaterials can be used, and it is possible that different metamaterials can be used in different locations of the terminal contact, the socket contact, and the insulating housing. When determining the location and selection of the metamaterials, the heat flow paths provided by the metamaterials can be considered. If the metamaterials convert heat into radiation, then the metamaterials can be placed such that emitted radiation is not re-absorbed by a nearby metamaterial or other connector structure. For example, the metamaterials 490 can be placed on the outside surfaces of the contacts, as shown in FIGS. 4-6. Because radiation is emitted from the surface of the metamaterial, metamaterial arrangements with more surface area provide better thermal management.

The metamaterials can be applied in any suitable manner. For example, some metamaterials have a back coated with an adhesive, including, for example, a pressure-sensitive adhesive, that allows the metamaterials to be directly applied to the contacts. The metamaterials can be placed to provide thermally conductive paths so that heat can flow more easily from within the insulating housing to outside of the insulating housing, which improves the thermal properties of the power connector. Such an arrangement of metamaterials on the contacts of the power connector allow more current and/or power to be transmitted before reaching the 30° C. above ambient temperature level.

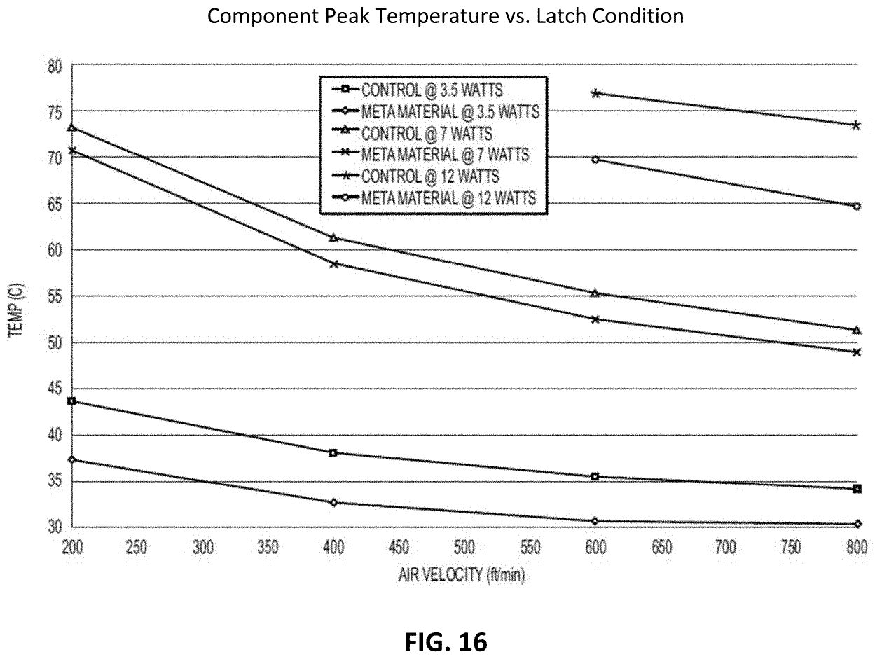

The metamaterial can reduce unwanted heat in an electrical connector by approximately 5° C.-15° C. at 3.5 Watts, approximately 5° C.-15° C. at 7 Watts, approximately 7° C.-15° C. at 12 Watts, or 5° C.-10° C., such as at a 30° C. temperature rise time, compared to an identical electrical connector without metamaterials. As shown in FIG. 16, the metamaterial reduces unwanted heat in a shielded transceiver, compared to an identical shielded transceiver without metamaterials, by approximately 3° C.-8° C. when the electrical connector is exposed to a wind tunnel air velocity of 200-800 feet/minute. Different types, sizes, and configurations of electrical or shielded optical connectors with metamaterials can achieve similar or superior results. Similarly, an electrical connector including metamaterial is cooler with respect to an identical electrical connector without the metamaterial when operated at the same current and/or power.

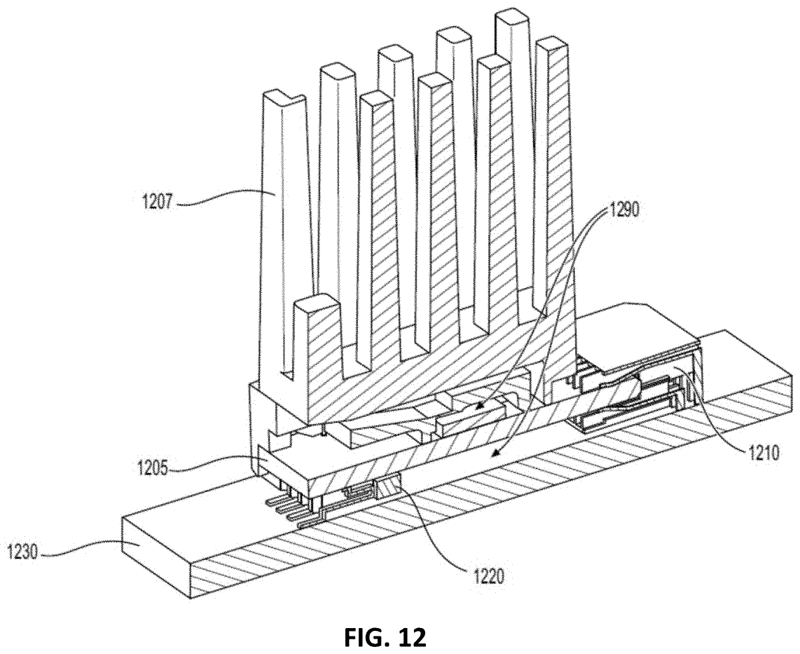

As mentioned above, optical modules also generate heat that can be managed with metamaterials. FIGS. 12-15 show optical modules or portions of optical modules. The metamaterials can be located between a heat source and thermal interface material (TIM) to improve thermal management. Examples of heat sources include the optical and electrical components of the optical module, including, for example, the electrical-to-optical components, including a vertical-cavity surface-emitting laser (VCSEL), and the optical-to-electrical components, including a transimpedance amplifier (TIA). Cooling optical or electrical transceiver components, as shown in, for example, FIGS. 12-14, such that a temperature of an adjacent VCSEL can be maintained between approximately −40° C. and 125° C., result in improved VCSEL performance, increased reliability, and longer lifetime.

For example, metamaterials can be applied to the metal housing or shield of an optical module to direct heat away from the VCSEL and/or other temperature sensitive devices. The metal housing or shield of the optical module or transceiver can include an integrally formed heat sink that defined fins. In some applications, an optical transceiver is plugged into a metal cage on a substrate. In this case, metamaterials can be applied to the metal cage. Some metal cages can include a heatsink that is in contact with the optical transceiver. Metamaterials can be applied to the heatsink such that the metamaterials are located between the heatsink and the optical transceiver to assist heat transfer. It is also possible to apply metamaterials to a hole in the cage or to make the cage out of metamaterials so that the cage functions as a heatsink. It is also possible to make the heatsink out of metamaterials. In this way, the size of a heat sink can be reduced or the need for a heat sink can be eliminated.

FIG. 12 is a sectional view of an example of an optical module. As shown, the optical module is an optical transceiver, for example, a FireFly™ optical transceiver, from Samtec, Inc. of New Albany, Ind. FIG. 12 shows the optical transceiver with a transceiver PCB 1205 and a heatsink 1207 connected to a first connector 1210 and a second connector 1220 located on a PCB 1230. Metamaterials 1290 can be located on or near the electrical components on the PCB of the transceiver, including, for example, the electrical-to-optical, such as the TIA, and/or the optical electrical components, such as the VCSEL.

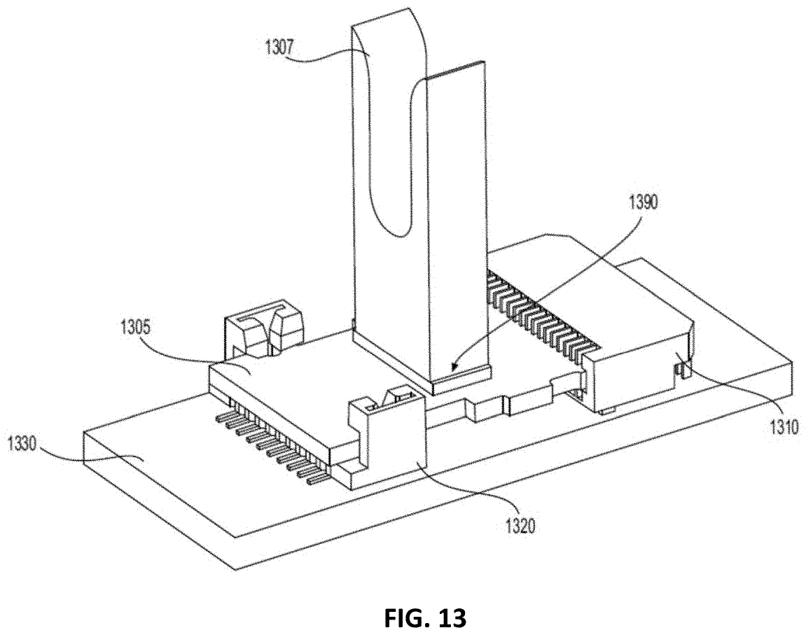

FIG. 13 shows another example of an optical transceiver. FIG. 13 shows the optical transceiver with a transceiver PCB 1305 and a heatsink 1307 connected to a first connector 1310 and a second connector 1320 located on a PCB 1330. Similarly to that shown in FIG. 12, metamaterials 1390 can be added to or near the electrical components to the optical transceiver shown in FIG. 13.

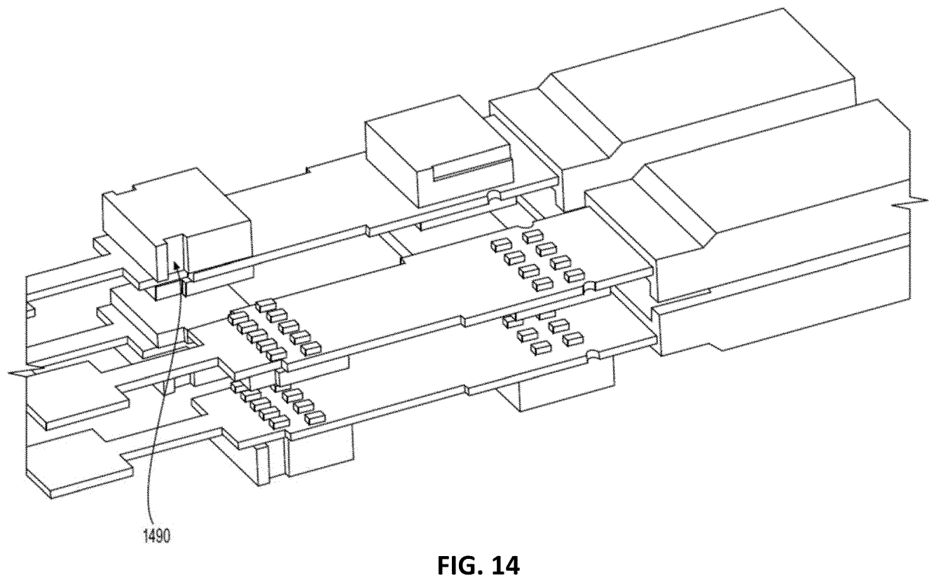

FIG. 14 shows an example of a quad small form-factor pluggable double density (QSFP-DD) transceiver. Metamaterials 1490 can be placed between any internal heat source and a TIM module attached to the housing of the QSFP-DD transceiver. If a metamaterial 1490 that converts heat to radiation is used, then the metamaterial 1490 can be selected such that the converted radiation is not absorbed by the resin parts, including, for example, the PCB, molded optical structure (MOS), etc. Such a metamaterial 1490 could be placed on the receiver IC, optical-to-electrical components, TIA, limiting amplifier, etc.

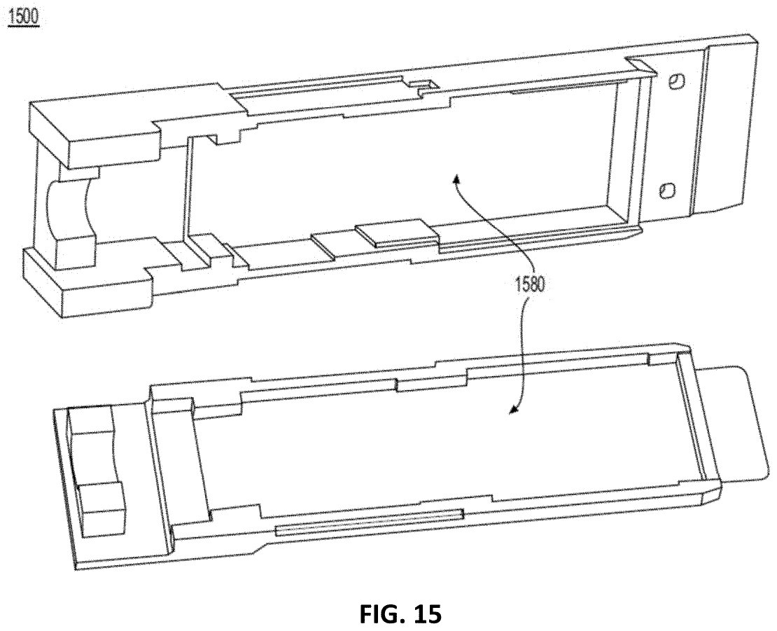

FIG. 15 shows an example of a housing 1500 of an optical transceiver. In this structure, it is possible to add a heat-radiating paint 1580, for example, Cooltech™ by Okitsumo, Inc. of Japan, on the inner surfaces of the housing 1500. Although the heat-radiating paint 1580 is shown as painted on inner surfaces of the housing 1500 of an optical transceiver, it is possible to paint any surface of an electrical connector and optical module. The heat-radiating paint 1580 can be used alone or in combination with any metamaterials discussed above.

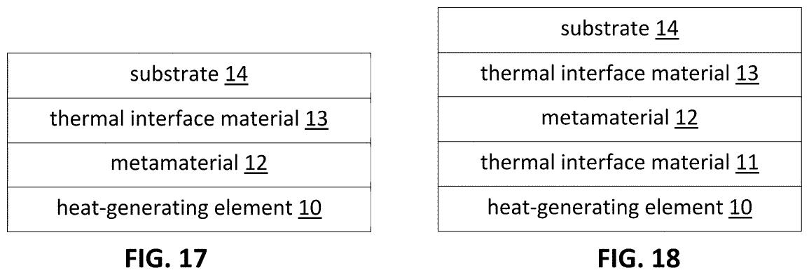

FIGS. 17 and 18 show possible arrangements of a metamaterial 12 with respect to a heat-generating element 10. In FIG. 17, the metamaterial 12 is located on the heat-generating element 10, and a thermal interface material (TIM) 13 is located between the metamaterial 12 and a substrate 14. The heat-generating element 10 can be any heat-generating element, including, for example, a contact in a connector; a processor, VCSEL, TIA in an optical transceiver, etc. The metamaterial 12 can be any of the metamaterials discussed above. The TIM 13 can be any thermal interface material, including, for example, a metal TIM, a thermal grease, a thermal adhesive, a thermal tape, a thermally conductive pad, etc. The substrate 14 can be any substrate. For example, the substrate 14 could be a portion of a housing of the heat-generating element 10, or the substrate 14 could be a heatsink adjacent the heat-generating element 10. If the heat-generating element 10 is a contact in a connector, then the substrate 10 can be a portion of the connector housing, including, for example, a portion of a liquid-crystal-polymer housing. FIG. 18 is similar to FIG. 17, except that a thermal interface material (TIM) 11 is located between the metamaterial 12 and the heat-generating element 10.

A method to reduce heat in a heated element 10 can include a step of placing a metamaterial 12 on, adjacent to, or in a heat path created by the heated element 10. The method can further include a step of placing the metamaterial 12 on, adjacent to, or in a heat path created by the heated element such that the metamaterial 12 is not exposed to an outside environment, such as moving gas or air. The metamaterial can be only a single planar-shaped panel, any panel devoid of heat dissipating fins or studs, or any metamaterial that does not contain thermoplastic.

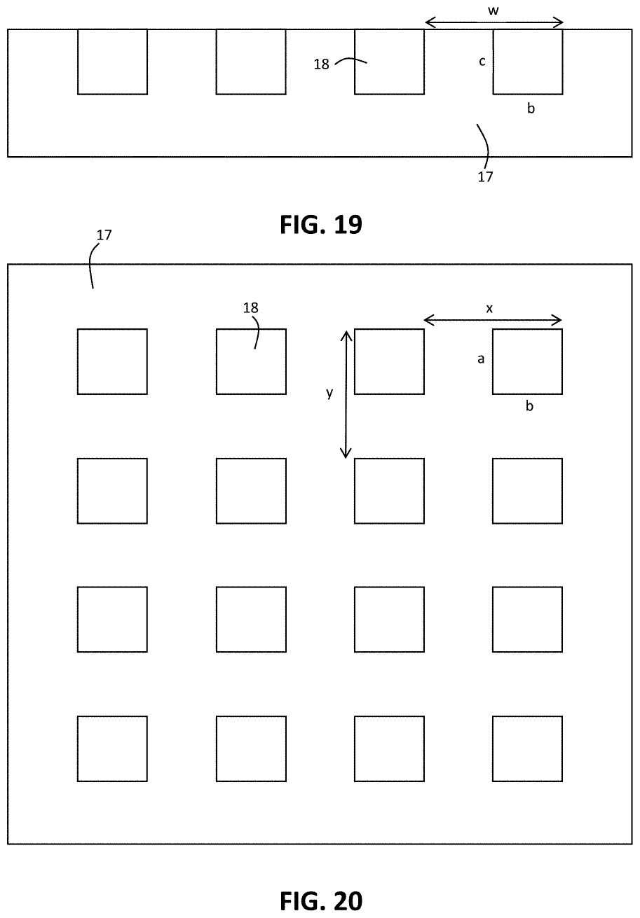

FIGS. 19 and 20 show an example of a metamaterial 17 with an array of surface holes 18. The surface holes 18 can have dimensions a, b, c and can have pitches x, y. In FIGS. 19 and 20, dimension a is the length of the surface hole 18, dimension b is the width of the surface hole 18, and dimension c is the height of the surface hole 18. In addition, pitch x is the pitch in the width direction, and pitch y is the pitch in the length direction. As an example, a metamaterial 17 can be an aluminum foil, dimensions a and b can be about 3 μm, dimension c can be about 10 μm, and pitches x, y can be about 5 μm. Other materials, dimensions, and pitches can be used. The dimensions a, b, c can be adjusted to change the resonances of the surface holes 18. The metamaterial can be aluminum, copper, etc. The dimensions a, b, c of the surface holes 18 can be chosen to emit infrared radiation. If the metamaterial is going to emit infrared radiation, then the metamaterial can be a material that radiates infrared radiation when heated, including, for example, aluminum, copper, etc.

The surface holes can be made by using any suitable method, including reactive ion etching (RIE), photolithography, focused ion beam (FIB) processing, nanoimprinting process using molds, anisotropic anodic etching, etc.

It should be understood that the foregoing description is only illustrative of the present invention. Various alternatives and modifications can be devised by those skilled in the art without departing from the present invention. Accordingly, the present invention is intended to embrace all such alternatives, modifications, and variances that fall within the scope of the appended claims.

1. An electrical connector comprising:
an electrically insulating housing;
an electrically conductive contact included in the electrically insulating housing; and
a metamaterial thermally connected to one of the electrically insulating housing or the electrically conductive contact; wherein
the metamaterial thermally cools the electrical connector or the contact.

2. An electrical connector comprising:
an electrically insulating housing;
an electrically conductive contact carried by the electrically insulating housing;
an electrically conductive shield; and
a metamaterial thermally connected to the electrically conductive shield.

3. The electrical connector of claim 1, wherein the metamaterial reduces unwanted heat by approximately 3° C.-15° C.

4. The electrical connector of claim 1, wherein the metamaterial reduces unwanted heat in a transceiver by approximately 3° C.-8° C. when the electrical connector is exposed to an air velocity of 200-800 feet/minute.

5. The electrical connector of claim 1, wherein the metamaterial reduces unwanted heat in an electrical connector by approximately 5° C.-15° C. at 3.5 Watts, approximately 5° C.-15° C. at 7 Watts, or approximately 7° C.-15° C. at 12 Watts.

6. The electrical connector of claim 1, wherein the electrical connector is cooler with respect to an identical electrical connector devoid of the metamaterial when operated at the same current and/or power.

7. The electrical connector of claim 1, further comprising a thermal interface material that is directly adjacent to at least one surface of the metamaterial.

8. The electrical connector of claim 1, wherein the metamaterial includes an array of surface holes.

9. A connector including a thermal metamaterial, wherein the thermal metamaterial provides heat flow paths from inside the connector to outside of the connector or converts heat into radiation.

10. The connector of claim 9, wherein the connector is an electrical connector, a power connector, or an optical module.

11. The connector of claim 9, wherein the thermal metamaterial includes an anisotropic composite in which high thermal conductivity fibers or asymmetric particles are included in a low thermal conductivity matrix to provide the heat flow paths.

12. The connector of claim 9, wherein the thermal metamaterial converts heat into radiation that is not absorbed by resin.

13. The connector of claim 9, further comprising a thermal interface material that is directly adjacent to at least one surface of the thermal metamaterial.

14. The connector of claim 9, wherein the thermal metamaterial includes an array of surface holes.

15. A cage assembly comprising:
a cage that receives a transceiver;
a heatsink connected to the cage; and
a metamaterial thermally connected to one of the cage or the heatsink; wherein
the metamaterial thermally cools the transceiver when the transceiver is plugged into the cage.

16. The cage assembly of claim 15, further comprising a thermal interface material that is directly adjacent to at least one surface of the metamaterial.

17. The cage assembly of claim 15, wherein the metamaterial includes an array of surface holes.

18. A transceiver assembly comprising:
the cage assembly of claim 15; and
a transceiver plugged into the cage.

19. The transceiver assembly of claim 18, wherein:
the transceiver includes a vertical-cavity surface-emitting laser (VCSEL); and
the metamaterial maintains a temperature of the VCSEL between approximately −40° C. and 125° C.

20. The transceiver assembly of claim 18, wherein the metamaterial includes an array of surface holes.

21. A connector comprising:
a housing;
an electrical contact in the housing; and
a metamaterial thermally connected to the electrical contact.

22. The connector of claim 21, further comprising a thermal interface material located between the electrical contact and the metamaterial.

23. The connector of claim 21, further comprising a thermal interface material located between the housing and the metamaterial.

24. The connector of claim 21, further comprising:
a first thermal interface material located between the electrical contact and the metamaterial; and
a second thermal interface material located between the housing and the metamaterial.

25. The connector of claim 21, wherein the metamaterial includes an array of surface holes.
